(19) United States
(12) Patent Application Publication
(10) Pub. No.: US 2024/0360023 A1
(43) Pub. Date: Oct. 31, 2024

(54) METHOD AND SYSTEM FOR BONDING HIGH FLUENCE OPTICS TO OPTOMECHANICAL ASSEMBLIES

(71) Applicant: KLA Corporation, Milpitas, CA (US)

(72) Inventor: Mandar Anand Paranjape, San Jose, CA (US)

(21) Appl. No.: 18/594,991

(22) Filed: Mar. 4, 2024

Related U.S. Application Data
(60) Provisional application No. 63/462,531, filed on Apr. 28, 2023.

(51) Int. Cl. C03B 29/16; G02B 7/00; G03F 7/00

(52) U.S. Cl. CPC C03B 29/16; C03B 2201/83; G02B 7/00; G03F 7/70833

(57) ABSTRACT

A method for binding a first optical element to a substrate is disclosed. The method may include receiving a first optical element and a substrate. The method may include positioning an indium foil between the first optical element and the substrate. The method may include securing the first optical element to the substrate to produce a pre-bonded assembly, wherein the indium foil is disposed between the first optical element and the substrate. The method may include heating the pre-bonded assembly above a melting temperature of the indium foil. The method may include cooling the pre-bonded assembly. The method may include releasing the pre-bonded assembly, wherein releasing the pre-bonded assembly releases a bonded structure.

### CROSS-REFERENCE TO RELATED APPLICATION

The present application claims the benefit under 35 U.S.C. § 119(e) of U.S. Provisional Application Ser. No. 63/462,531, filed Apr. 28, 2023, which is incorporated herein by reference in the entirety.

### TECHNICAL FIELD

The present disclosure relates to the production of optical systems, and, in particular, to bonding optical elements within optical systems without affecting the optical properties of the optical elements.

### BACKGROUND

High-power deep UV laser-based illumination systems include optical elements such as mirrors, lenses, birefringent crystals, non-linear optical crystals and waveplates, polarizer beam splitters. Securing these optical elements within the system (e.g., by bonding the optical elements to a substrate is often difficult. Current methods for binding optical elements to substrates often result in a change in one or more optical properties of the optical element including, but not limited to, changes in reflection, transmission, wavefront, polarization purity and stress-induced birefringence.

Therefore, it is desirable to provide methods that overcomes the shortfalls of the previous approaches discussed above.

### SUMMARY

A method for binding a first optical element to a substrate is disclosed, in accordance with one or more embodiments of the disclosure. In one embodiment, the method includes receiving a first optical element and a substrate. In another embodiment, the method includes positioning an indium foil between the first optical element and the substrate. In another embodiment, the method includes the first optical element to the substrate to produce a pre-bonded assembly, wherein the indium foil is disposed between the first optical element and the substrate. In another embodiment, the method includes heating the pre-bonded assembly above a melting temperature of the indium foil. In another embodiment, the method includes cooling the pre-bonded assembly. In another embodiment, the method includes releasing the pre-bonded assembly, wherein releasing the pre-bonded assembly releases a bonded structure.

A system for bonding a first optical element to a substrate is disclosed, in accordance with one or more embodiments of the disclosure. In one embodiment, the system includes a base plate configured to receive a plurality of elements and configured to receive the first optical element and the substrate. In another embodiment, the system includes a heating element thermally coupled to the base plate. In another embodiment, the system includes a top plate coupled to a top end of the plurality of retaining elements, wherein a tightening of the plurality of retaining elements into the base plate increases a clamping force upon the first optical element and the substrate.

An apparatus is disclosed, in accordance with one or more embodiments of the disclosure. In one embodiment, the apparatus includes a first optical element. In another embodiment, the apparatus includes a substrate In another embodiment, the apparatus includes indium foil, wherein the first optical element is bonded to the substrate via the indium foil.

It is to be understood that both the foregoing general description and the following detailed description are exemplary and explanatory only and are not necessarily restrictive of the invention as claimed. The accompanying drawings, which are incorporated in and constitute a part of the specification, illustrative embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures in which:

FIG. 1 illustrates a block diagram view of a system for bonding a first optical element to a substrate, in accordance with one or more embodiments of the present disclosure.

FIG. 2 illustrates a simplified schematic view of a clamp assembly for bonding a first optical element to a substrate via indium foil, in accordance with one or more embodiments of the present disclosure.

FIG. 3 illustrates a simplified schematic view of a clamp assembly for bonding a first optical element to a second optical element via indium foil, in accordance with one or more embodiments of the present disclosure.

FIG. 4 illustrates a simplified schematic view of a system for bonding a first optical element to a second optical element, the system including a clamp assembly and a gas purge sub-system, in accordance with one or more embodiments of the present disclosure.

FIG. 5 illustrates a process flow diagram depicting a method for bonding a first optical element to a substrate, in accordance with one or more embodiments of the disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

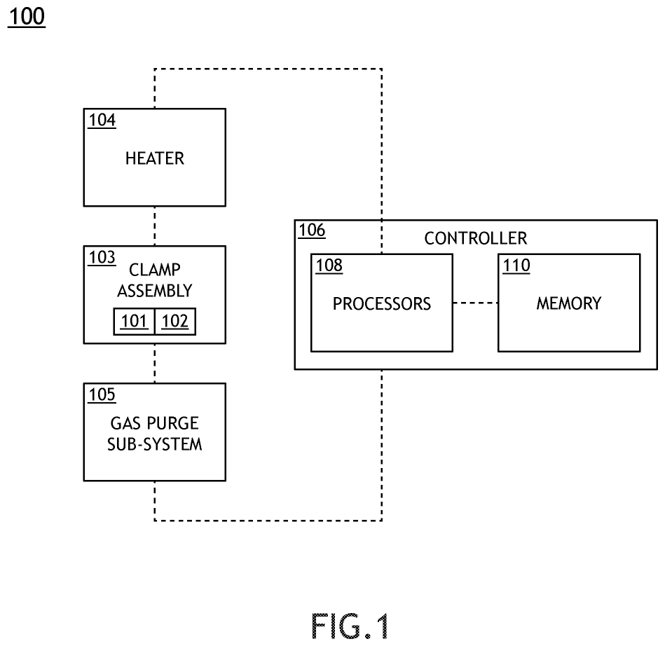

FIGS. 1 through 5 illustrate a system and method for bonding an optical element to a substrate. Embodiments of the present disclosure are directed to the use of indium foil as a bonding agent that bonds the optical element to the substrate. Embodiments of the present disclosure are also directed to a clamp assembly that secures the optical element to the substrate, with the indium foil placed at the interface of the optical element and the substrate (e.g. as a sandwich layer). Once the optical element and substrate are secured, the clamp assembly is subjected to predetermined pressures and temperatures, effectively producing a strongly bonded optical element/substrate apparatus due to the bonding action of the indium foil. Because the indium has a relatively low melting point (156° C.), the apparatus can be reworked by applying heat above the melting point.

The embodiments of the present disclosure are particularly advantageous for several reasons. For example, the bonding method reduces or eliminates stress-induced degradation often seen in mechanical clamping. In another example, the bonding method reduces or eliminates subsequent outgassing, and is not especially sensitive to bonding materials with different coefficients of thermal expansion (CTE) as often seen in epoxy bonding. In another example, the bonding methods do not utilize potentially damaging high temperatures often seen in soldering methods. Finally, the bonding method requires considerably less labor and time costs often seen in optical binding.

FIG. 1 illustrates a conceptual view of a system 100 for bonding a first optical element 101 to a substrate 102, in accordance with one or more embodiments of the present disclosure. In embodiments, the system 100 includes a clamp assembly 103, a heater 104, a gas purge sub-system 105, and a controller 106. In embodiments, the clamp assembly 103 is configured to clamp the first optical element 101 to the substrate 102 during the bonding process. In embodiments, the heater 104 is configured to heat the first optical element 101 and the substrate 102 to a working temperature during the bonding process (e.g., while the first optical element 101 and the substrate 102 are disposed in the clamp assembly 103. In embodiments, the gas purge subsystem 105 is configured to purge the clamp assembly 103, including the first optical element 101 and the substrate 102, with an inert gas.

In embodiments, the controller 106 includes one or more processors 108 and memory 110. For example, the memory 110 may maintain program instructions configured to cause the one or more processors 108 to carry out any of the one or more process steps described throughout the present disclosure.

In embodiments, the one or more processors 108 of the controller 106 are communicatively coupled to the heater 104 and the gas purge sub-system 104. In this regard, the one or more processors 108 are configured to control the temperature of the clamp assembly 103, the first optical element 101, and the substrate 102 via the heater 104. Also, the one or more processors 108 are configured to control the flow of inert gas through the clamp assembly 103 via the gas purge sub-system 105.

In embodiments, the heater 104 includes any heating element that can raise a temperature of the first optical element 101 and the substrate 102 above the melting point of indium (156° C.). The heater 104 may utilize any type of heat energy for heating including, but not limited to, conductive heat, convective heat, and radiative heat. The heater 104 may include any type of heater form. For example, the heater 104 may include a heater that raises the temperature of the first optical element 101 and the substrate 102 mainly through conduction. For instance, the heater 104 may include a cartridge heater, such as a ¼″ cartridge heater.

In embodiments, the heater 104 is controlled (e.g., via the one or more processors 108 acting as a temperature controller) to heat the first optical element 101 and the substrate 102 to a temperature (e.g., a working or melting temperature). For example, the heater 104 may be configured to heat the first optical element 101 and the substrate 102 to at least 156° C., to at least 160° C., to at least 165° C., or to at least 175° C., or to a temperature higher than 175° C. For instance, the heater 104 may be configured to heat the first optical element 101 and the substrate 102 to within a range of 156° C. to 175° C. In another instance, the heater 104 may be configured to heat the first optical element 101 and the substrate 102 to within a range of 156° C. to 165° C. In another instance, the heater 104 may be configured to heat the first optical element 101 and the substrate 102 to within a range of 165° C. to 175° C.

In embodiments, the heater 104 is controlled, via the one or more processors 108, to heat or cool the first optical element 101 and the substrate 102 via a ramp rate (e.g., ° C./min). For example, the heater 104 may be configured to change the temperature approximately 1° C./min. In another example, the heater 104 may be configured to change the temperature approximately 2° C./min. In another example, the heater 104 may be configured to change the temperature approximately 0.5° C./min. In another example, the heater 104 may be configured to change the temperature approximately 0.25° C./min. Controlling the ramp rate of the heater 104 ensures thermalization of the first optical element 101 with another substrate 102, which significantly reduces thermal stress in crystal optical elements (e.g., single crystal optical elements) such as CaF₂ crystals, MgF₂ crystals, beta barium borate (BBO) crystals and cesium lithium borate (CLBO) crystals.

In embodiments, the gas purge sub-system 105 includes any gas dispersing system for the dispersal and purging of an inert gas (e.g., nitrogen, argon, carbon dioxide, helium). The gas purge sub-system 105 may include a gas reservoir and one or more valves, with at least one valve controlled by the controller 106.

In embodiments, the first optical element 101 may include any type of optical element including, but not limited to, a lens, a mirror, a window, a flat, a filter, a prism, or a beamsplitter. The first optical element 101 may include any optical element material or component including but not limited to CaF₂, MgF₂, BBO, CLBO, KTP, PPKTP, LBO, DKDP, ADP, KDP, LiIO3, KNbO3, LiNbO3, AgGaS2, AgGaSe2 BaF2, LiF, YAG, TGG, TiO2, ZnS, ZnSe, GaAs, or SiGe. The first optical element may include a coating including but not limited to, an oxide coating, Ta2O5, ZrO2, HfO2, Al2O3, SiO2, Nb2O5, TiO2, FS, SBO, a fluoride coating, LiF, CaF2, MgF2, LaF3, AlF3, LiF, LaF3, GdF3, or NdF3. In embodiments, the substrate 102 may include any material to be bonded to the first optical element 101 including, but not limited to, a mount, a floor, a base, a metal surface, or a second optical element. The second optical element may include any optical element as described for the first optical element 101.

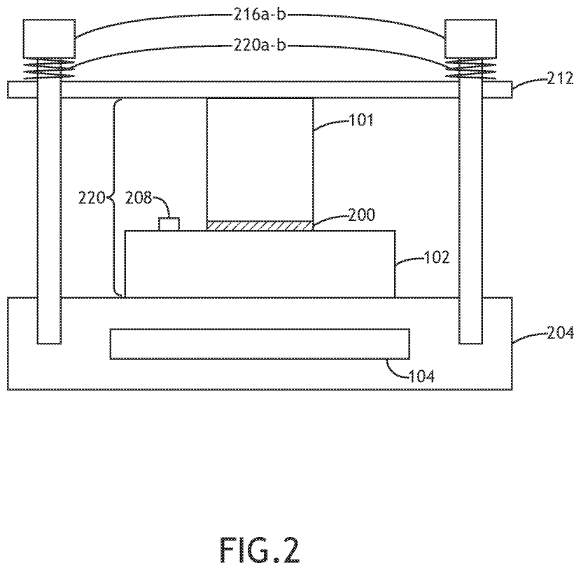

FIG. 2 illustrates a simplified schematic view of a clamp assembly 103 for bonding a first optical element 101 (e.g., a CaF₂ polarizing beamsplitter cube (PBSC)) to a substrate 102 (e.g., a metal mount for the first optical element 101, such as a nickel-plated aluminum mount) via indium foil 200, in accordance with one or more embodiments of the present disclosure. In embodiments, the clamp assembly 103 includes one or more of a base plate 204, the heater 104, a thermometer 208, a top plate 212, and a plurality of retaining elements 216a-b (e.g., retaining screws) configured to couple to the base plate 204 and a top end of the top plate 212. In embodiments, the clamp assembly includes a plurality of spring clamps that secure the plurality of retaining elements 216a-b in position. The thermometer 208 may be communicatively coupled to the one or more processors 108. When clamped together, the first optical element 101, the substrate 102, and the indium foil 200 form a pre-bonded assembly 220. Tightening the retaining elements 216a-b increases the clamping force upon the pre-bonded assembly 220.

When in use, the clamp assembly 103 receives upon the base plate 204 the first optical element 101 and the substrate 102, with the indium foil 200 positioned between the first optical element 101 and the substrate 102. Either the first optical element 101 or the substrate 102 may be positioned first upon the base plate 204. The top plate 212 is then placed upon the first optical element 101/substrate 102 assembly. The retaining elements 216a-b are then secured to the base plate 205 while mechanically coupled to the top plate 212, effectively clamping the first optical element 101 and the substrate 102 to the clamp assembly, with the indium foil 200 sandwiched (e.g., disposed) between the first optical element 101 and the substrate 102 to the clamp assembly.

The indium foil 200 may include any indium-containing foil. For example, the indium foil 200 may include foil that includes greater than 50% indium, greater than 66% indium, greater than 80% indium, greater than 90% indium, greater than 95% indium, greater than 99.9% indium, or foil that is 99.99% indium or greater. For example, the indium foil 200 may include foil that is 99.99% indium or approximately 99.99% indium. The indium foil 200 may be thickness including but not limited to a 2 mm thickness, a 0.127 mm thickness, a 0.1 mm thickness, an 80 μm thickness, a 60 μm thickness, a 50 μm thickness, a 40 μm thickness, or approximate thicknesses thereof. For example, the indium foil 200 may include a 99.99% indium-containing foil with a thickness of 50 μm.

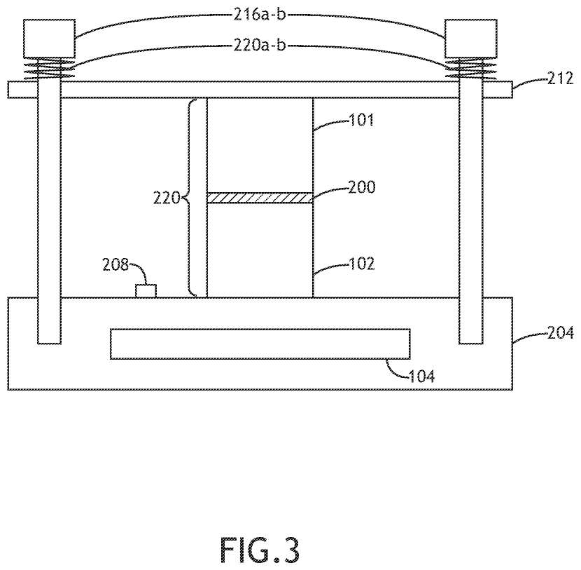

FIG. 3 illustrates a simplified schematic view of the clamp assembly 103 for bonding a first optical element 101 to a second optical element (e.g., substrate 102) via indium foil 200, in accordance with one or more embodiments of the present disclosure. The thermometer 208 may be located on the base plate 204, the substrate 102, or other component of the clamp assembly 103.

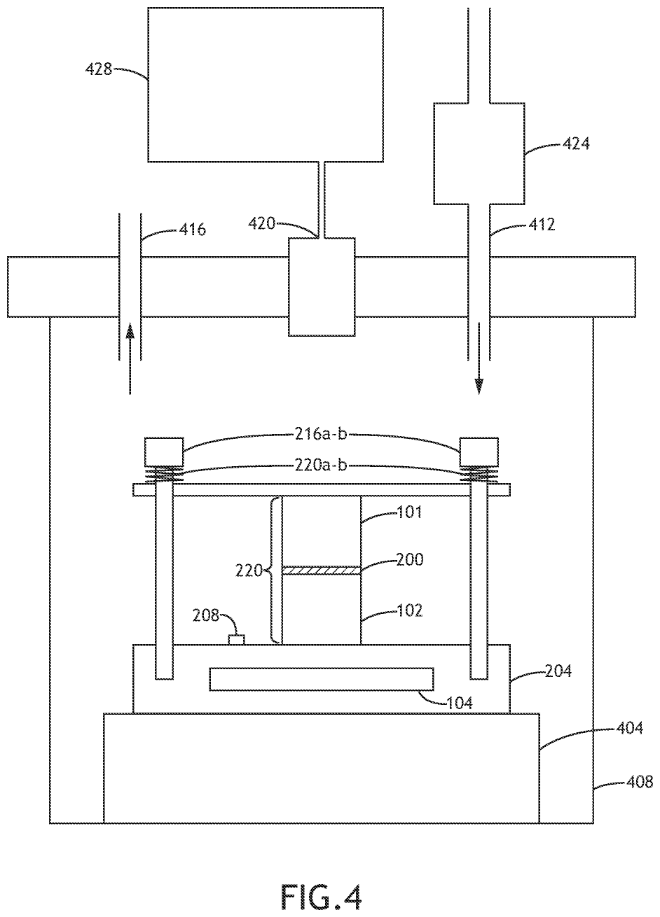

FIG. 4 illustrates a simplified schematic view of the system 100 for bonding a first optical element to a second optical element, the system including the clamp assembly, the heater 104, and the gas purge sub-system 105, in accordance with one or more embodiments of the present disclosure. The system 100 of FIG. 4 may include one or more components of the bond assemblies 103 of FIGS. 2-3, and may further include one or more thermal insulator plates 404, a container 408, an input purge line 412, and output purge line 416, and electrical feed through 420 (e.g., for feeding the thermometer 208, heater 104, and associated wires into the container 408), an air filter 424, and a temperature controller 428 (e.g., including at least one of the one or more processors).

In embodiments, the container 408 is configured to contain the clamp assembly 103 while the first optical element 101 and substrate 102 are being purged with inert gas during the heating (e.g., baking) process. The container 408 may include stainless steel, which provides an isothermal environment for the clamp assembly 103. The container 408 may further include a top flange to allow connectivity via the input purge line 412, output purge line 416, and the electric feed through 420.

In embodiments, the gas purge sub-system 105 purges the first optical element 101, substrate 102, and indium foil 200 with filtered inert gas. For example, the gas purge sub-system 105 may purge the first optical element 101, substrate 102, and indium foil 200 with Airborne Molecular Contamination (AMC)-filtered inert gas (e.g., such as ultrapure N₂ gas). In embodiments, the inert gas used to purge the first optical element 101, substrate 102, and indium foil 200 is flowed at a rate of 0.1 L/min, at a rate of 0.25 L/min, at a rate of 0.5 L/min, at a rate of 1.0 L/min, or at a rate of 2.0 L/min, or at approximate rates thereof. For example, the first optical element 101, substrate 102, and indium foil 200 may be purged using AMC-filtered ultrapure N₂ gas at the rate of 0.5 L/min.

In embodiments, the one or more processors 108 of the controller 106 of the system 100 controls the heater 104. For example, the one or more processors 108 of the controller 106 of the system 100 may perform at least one of controlling the ON/OFF switching of the heater 104, controlling the ramping of the heater 104, controlling a soak time or holding time of the heater 104 at a specific temperature, monitoring the thermometer 208, and changing a heating parameter based on a reading of the thermometer 208. In embodiments, the one or more processors 108 of the controller 106 of the system controls the gas purge sub-system 105. For example, the one or more processors 108 of the controller 106 of the system 100 may perform at least one of controlling the flow of inert gas into and/or out of the container 408.

In embodiments, the system 100 includes a user interface device communicatively coupled to the one or more processors 108 of controller 106. The user interface device may be utilized by controller 106 to accept information, selections and/or instructions from a user. For example, a display may be used to display data or a prompt to a user (not shown). In turn, a user may input information, a selection and/or instructions into the memory 110 of the controller 106 via the user interface device.

While the foregoing description has focused on a heater 104 and gas purge sub-system 105 placed in communication with the one or more processors 108, such a configuration is not a limitation on the scope of the embodiments of the present disclosure. In embodiments, a heating protocol or gas purge protocol as described herein may be entered into the memory 110 of the controller 106 by a user via user interface. In this regard, the heating and gas purging described previously herein may be carried out with the protocols entered into memory 110 via user interface.

The one or more processors 108 of controller 106 may include any one or more processing elements known in the art. In this sense, the one or more processors 108 may include any microprocessor-type device configured to execute software algorithms and/or instructions. In embodiments, the one or more processors 108 may consist of a desktop computer, mainframe computer system, workstation, image computer, parallel processor, or other computer system (e.g., networked computer) configured to execute a program configured to operate the system 100, as described throughout the present disclosure. It should be recognized that the steps described throughout the present disclosure may be carried out by a single computer system or, alternatively, multiple computer systems. In general, the term “processor” may be broadly defined to encompass any device having one or more processing elements, which execute program instructions from a non-transitory memory medium 110. Moreover, different subsystems of the system 100 (e.g., heater 104, gas purge sub-system 105, or user interface) may include a processor or logic elements suitable for carrying out at least a portion of the steps described throughout the present disclosure.

The memory medium 110 may include any memory medium known in the art suitable for storing program instructions executable by the associated one or more processors 108. For example, the memory medium 110 may include, but is not limited to, a read-only memory, a random-access memory, a magnetic or optical memory device (e.g., disk), a magnetic tape, a solid-state drive and the like. In embodiments, the memory medium 110 is configured to store one or more results from the heater 104, the gas purge sub-system 105 and/or the output of the various data processing steps described herein. It is further noted that memory medium 110 may be housed in a common controller housing with the one or more processors 108. In embodiments, the memory medium 110 may be located remotely with respect to the physical location of the processors and controller 106. For instance, the one or more processors 108 of controller 106 may access a remote memory (e.g., server), accessible through a network (e.g., internet, intranet and the like).

It is further noted that, while FIG. 1 depicts the controller 106 as being embodied separately from the heater 104 and gas purge sub-system 105, such a configuration of system 100 is not a limitation on the scope of the present disclosure, but is provided merely for illustrative purposes. For example, the controller 106 may be embodied in a controller of the heater 104 and gas purge sub-system 105.

The user interface device may include any user interface known in the art. For example, the user interface may include, but is not limited to, a keyboard, a keypad, a touchscreen, a lever, a knob, a scroll wheel, a track ball, a switch, a dial, a sliding bar, a scroll bar, a slide, a handle, a touch pad, a paddle, a steering wheel, a joystick, a bezel input device or the like.

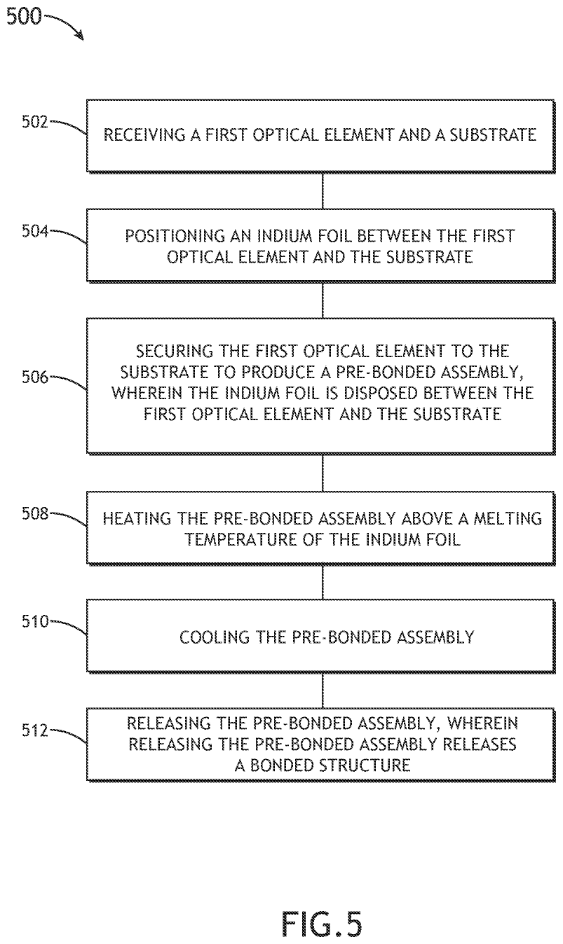

FIG. 5 illustrates a process flow diagram depicting a method 500 for bonding a first optical element 101 to a substrate 102. In embodiments, the method 500 includes a step 502 of receiving the first optical element 101 and the substrate 102. In embodiments, the method 500 includes a step 504 of positioning the indium foil 200 between the optical element 101 and the substrate 102.

In embodiments, the method includes a step 506 of clamping (e.g., securing, fastening, attaching) the first optical element 101 to the substrate 102, wherein clamping the first optical element 101 to the substrate 102 produces a pre-bonded assembly 220, wherein the indium foil 200 is sandwiched (e.g., disposed) between the first optical element 101 and the substrate 102. The clamping of the first optical element 101 to the substrate 102 includes a clamping force. Clamping forces may include, but not be limited to, clamping with a vertical clamping force of approximately 5 N or less, of approximately 10 N, of approximately 15 N, of approximately 20 N, or of 30 or more N. Clamping forces may further include, but not be limited to, clamping with a horizontal retention force of approximately 3.0 N or less, of approximately 4.5 N, or of approximately 6.0 N or more. For example, the clamping of the first optical element 101 and the substrate 102, such as the clamping of a CaF₂ PBSC with a metal mount, may include a vertical clamping force of 15 N and a horizontal retention force of 4.5 N.

In embodiments, the method 400 includes a step 508 of heating the pre-bonded assembly 220 (e.g., the pre-bonded assembly 220 including the first optical element 101, the substrate 102, and the indium foil 200) above the melting temperature of the indium foil (e.g., 156° C.). The heating may include any heating point or range of heating points as disclosed herein. For example, the step 508 of the method 500 may include heating the pre-bonded assembly 220 to 165° C. by a heat ramp protocol that increases the temperature of the pre-bonded assembly 220 by approximately 1° C./min. Upon reaching the targeted temperature, the pre-bonded assembly 220 may remain (e.g., be held) at the target temperature for a predetermined soak or holding time. The soak time may be approximately one hour or less, approximately two hours, approximately three hours, approximately four hours, approximately five hours, or approximately six hours or more. For example, the pre-bonded assembly 220 may be held at 165° C. for four hours.

In embodiments, the method 400 includes a step 510 of cooling the pre-bonded assembly 220 (e.g., to room temperature). The cooling of the pre-bonded assembly 220 may include a ramp protocol as described herein. For example, the pre-bonded assembly 220 may be cooled at a rate of 1° C./min. In embodiments, the method includes a step 512 of releasing pre-bonded assembly 220, wherein releasing the pre-bonded assembly 220 releases a bonded structure (e.g. containing the first optical element 101, the substrate 102, and the indium foil 200 that are bonded together). The bonded structure can then be incorporated into an appropriate optical system.

In embodiments, an apparatus is disclosed. The apparatus includes a bonded structure made of the first optical element 101, the substrate 102, and the indium foil 200, wherein the first optical element 101 is bonded to the substrate 102 via the indium foil. The first optical element 101 may include any optical type or material as disclosed herein. For example, the first optical element 101 of the bonded structure may include CaF₂, such as a CaF₂ beamsplitter. The substrate 102 of the bonded structure may include metal, such as aluminum, nickel, or nickel-plated aluminum.

In embodiments, the bonded structure has a natural frequency that greater than the natural frequency of an apparatus containing the same components (e.g., the first optical element 101 and the substrate 102), but bonded by other methods, such as clamping without a bonding element such as indium foil 200. The bonded structure may have a natural frequency above 300 Hz, above 500 Hz, above 750 Hz, or above 1 kHz. For example, while a pre-bonded assembly without indium foil 200 may have a natural frequency below 300 Hz, the bonded structure of this disclosure will have a natural frequency above 1 kHz. Apparatuses with higher natural frequencies are generally more stable than apparatuses with lower natural frequencies.

The bonded structure of the current disclosure has several advantages over bonded assemblies of the following technologies.

In the case of mechanical clamping, optical components are secured using spring flexures, spring caps or otherwise retained by mechanical means such as flexures and set screws. Even though mechanical clamping is a common method to mount a first optical element 101 to a substrate 102, these mounts need to be carefully designed to reduce clamping forces especially for single crystals like CaF₂ or MgF₂ to avoid stress-induced birefringence or damage to the optics while maintaining optical alignment during tool or spares shipment where these parts can experience shocks of the order of 10 G to 25 Gs. These are conflicting requirements, as weaker clamping forces can result in misalignment during shipping and handling while strong clamping forces can result in optical performance degradation or optical component chipping and breakage. Optical performance degradation may result in stress-induced birefringence and induced wavefront error. Also, the resultant natural frequencies of a bonded structure produced by mechanical clamping are typically limited to <300 Hz.

In the case of epoxy bonding, the ends of the optical components and optomechanical part are coated with a thin layer of epoxy, brought into contact, and then cured at room temperature over time or cured by heat or UV light. In deep ultraviolet (DUV) optical systems, epoxy bonding needs to be designed carefully to avoid any exposure to scattered or direct DUV exposure to the epoxy. Any exposure to UV light will result in outgassing resulting in photo-contamination damage, also epoxy bond strength may be seriously compromised by UV exposure. This often involves designing metallic shields for scattered light and or additional reflective coatings to protect epoxied parts from scattered light. Also, epoxied parts are not easily reworkable. Epoxies generally have thermally mismatched coefficients of thermal expansion (CTE), which can result in bond breaking with temperature swings.

In the case of optical bonding, two optical components are polished smooth on at least one surface, and the two optically polished surfaces are brought into close contact at room temperature. Under these extremely smooth conditions, the van der Waals and other interatomic and molecular forces are maximized, and a bond is thus formed by atomic and molecular attractions between the surfaces. Optical bonding can be further improved by chemical activation and diffusion bonding. Optical bonding has limited success in bonding optics to metal parts, and is expensive, as surfaces need to be optically polished, and often surfaces need to be further chemically activated to create strong bonds. Chemical activation can also lead to photo-contamination damage.

In the case of indium bonding/soldering, indium or other low-temperature eutectic alloys are often used to solder chipsets or wafers to heatsinks or other substrates. This technique also uses soldering flux to aid the soldering. However, Indium soldering is not useful for bonding high fluence optics as soldering creates localized heating which may result in thermally induced stress in the bulk of the glass/single crystals. For coated (antireflective, reflective or polarizer coatings) optics there is a high probability of damage to the optical coatings from localized heating and thermal stress. There is also danger of photo contamination to the optics and coatings from gaseous fumes from hot soldering element and soldering flux

In embodiments, the method 400 includes a step of purging the pre-bonded assembly 220 with an inert gas (e.g., via the gas purge sub-system 105). For example, the pre-bonded assembly 220 may be purged using AMC-filtered ultrapure N₂ gas at the rate of 0.5 L/min.

In embodiments, the method 400 includes a step of reworking the bonded structure. For example, the bonded structure can be heated to a temperature above the melting point of the indium foil. Once the indium foil has melted, the bonded structure will readily be separated into the first optical element 101 and the substrate 102. The now-separated first optical element 101 and the substrate can then be reassembled into a new pre-bonded assembly 220 as described herein.

While implementations of method 400 are discussed herein, it is further contemplated that various steps of method 400 may be included, excluded, rearranged, and/or implemented in many ways without departing from the essence of the present disclosure. Accordingly, the foregoing embodiments and implementations of method 400 are included by way of example only and are not intended to limit the present disclosure in any way.

All of the methods described herein may include storing results of one or more steps of the method embodiments in a memory medium. The results may include any of the results described herein and may be stored in any manner known in the art. The memory medium may include any memory medium described herein or any other suitable memory medium known in the art. After the results have been stored, the results can be accessed in the memory medium and used by any of the method or system embodiments described herein, formatted for display to a user, used by another software module, method, or system, etc. Furthermore, the results may be stored “permanently,” “semi-permanently,” temporarily,” or for some period of time. For example, the memory medium may be random access memory (RAM), and the results may not necessarily persist indefinitely in the memory medium.

It is further contemplated that each of the embodiments of the method described above may include any other step(s) of any other method(s) described herein. In addition, each of the embodiments of the method described above may be performed by any of the systems described herein.

Bonding of the first optical component 101 to the substrate 102, as described in this disclosure, is performed in the AMC-controlled environment with (<0.1 ng/L total outgassing) with inert N₂ purge gas. This ensures an ultraclean environment during bonding process at elevated temperatures. N₂ gas is used to ensure oxygen stoichiometry is unchanged in the optical coatings (e.g., oxides like SiO₂, HfO₂, Al₂O₃).

As disclosed herein, bonding temperature is kept at or near 165° C. which is lower than the 350° C. for dense IBS optical coatings (antireflective or high reflective) on the optically surfaces. Slow ramp rates (0.5° C.-1° C./min) makes sure single crystals like CaF₂ still remain optically uniform or adversely affecting optical qualities of the optical coatings. For example, the ramp rates may protect sensitive optical and metal surfaces used in DUV and extreme ultraviolet (EUV) applications during the bonding process to reduce risk of photocontamination. The slow heating and cooling ramp rates (e.g., 0.5° C.-1° C.) ensure thermalization of the first optical element 101 with the substrate 102 to be bonded. This significantly reduces thermal stresses in single-crystal optical elements such as, but not limited to, CaF₂, MgF₂, BBO and CLBO crystals. This ensures little to no optical performance degradation of the optical elements.

The ductility of indium foil 200 allows materials with different coefficients of thermal expansion (CTE) to be joined together. Indium easily deforms under pressure, fills voids between two surfaces, and can be used at cryogenic temperatures. No surface preparation or polishing is needed to bond the two surfaces. Indium metal is impervious to scattered DUV light and does not outgas, unlike epoxies. The resultant indium foil bond is impervious to DUV scattered DUV light. Indium foil also provides excellent thermal contact between optics and other optics or mechanical parts, and bonded indium parts can be reworked or manipulated by reheating above 156° C. Using indium foil 200, various optical materials like fused silica, CaF₂, MgF₂, Non-linear optical crystals like BBO, CLBO can be bonded to metals like Ni-plated Aluminum, copper, stainless steel or to other optical materials. Ramp rates and soak times may need to be optimized for bonding different materials.

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touchpad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components, and/or wirelessly interactable and/or wirelessly interacting components, and/or logically interacting and/or logically interactable components.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed:

1. A method for binding a first optical element to a substrate comprising:
receiving a first optical element and a substrate;
positioning an indium foil between the first optical element and the substrate;
securing the first optical element to the substrate to produce a pre-bonded assembly, wherein the indium foil is disposed between the first optical element and the substrate;
heating the pre-bonded assembly above a melting temperature of the indium foil;
cooling the pre-bonded assembly; and
releasing the pre-bonded assembly, wherein releasing the pre-bonded assembly releases a bonded structure.

2. The method of claim 1, further comprising purging the pre-bonded assembly with an inert gas.

3. The method of claim 1, further comprising reworking the bonded structure.

4. The method of claim 3, wherein reworking the bonded structure comprises heating the bonded structure above the melting temperature of the indium foil.

5. The method of claim 1, wherein the substrate comprises a metal layer.

6. The method of claim 1, wherein the first optical element comprises CaF₂.

7. The method of claim 1, wherein the substrate comprises a second optical element.

8. The method of claim 1, wherein heating the pre-bonded assembly above the melting temperature of the indium foil comprises heating the pre-bonded assembly to 102 to within a range of 156° C. to 175° C.

9. The method of claim 1, wherein heating the pre-bonded assembly above the melting temperature of the indium foil comprises heating the pre-bonded assembly to 165° C.

10. The method of claim 9, wherein the pre-bonded assembly is heated to 165° C. for four hours.

11. The method of claim 1, wherein the indium foil comprises greater than 99.99 percent indium.

12. The method of claim 1, wherein the indium foil comprises a thickness of thickness of 50 μm.

13. A system for bonding a first optical element to a substrate comprising:
a base plate configured to receive a plurality of retaining elements and configured to receive the first optical element and the substrate;
a heating element thermally coupled to the base plate; and
a top plate coupled to a top end of the plurality of retaining elements, wherein a tightening of the plurality of retaining elements into the base plate increases a clamping force upon the first optical element and the substrate.

14. The system of claim 13, further comprising:
a container configured to contain the base plate and the top plate, comprising:
an input purge line; and
an output purge line.

15. The system of claim 14 further comprising an air filter configured in-line with the input purge line.

16. The system of claim 13, further comprising a thermometer and a temperature controller.

17. An apparatus comprising:
a first optical element;
a substrate; and
indium foil, wherein the first optical element is bonded to the substrate via the indium foil.

18. The apparatus of claim 17, wherein the first optical element comprises CaF₂.

19. The apparatus of claim 17, wherein the substrate comprises metal.

20. The apparatus of claim 19, wherein the substrate comprises nickel.

21. The apparatus of claim 17, wherein the apparatus comprises a natural frequency greater than 1 kHz.
